(19) United States
(12) Patent Application Publication
(10) Pub. No.: US 2004/0031436 A1
(43) Pub. Date: Feb. 19, 2004

(54) Scatter-free UV optical fluoride crystal elements for <200NM laser lithography and methods

(76) Inventors: Michael W. Price, Corning, NY (US); Gail A. Rodriguez, Bath, NY (US)

Correspondence Address: CORNING INCORPORATED, SP-TI-3-1, CORNING, NY, 14831

(21) Appl. No.: 10/629,397

(22) Filed: Jul. 29, 2003

Related U.S. Application Data
(60) Provisional application No. 60/401,822, filed on Aug. 7, 2002.

(51) Int. Cl. C30B 1/00

(52) U.S. Cl. 117/2

(57) ABSTRACT

The invention provides a scatter-free below 200 nm wavelength transmitting optical fluoride lithography crystal for use with below 200 nm laser light. The invention includes making below 200 nm wavelength transmitting optical fluoride lithography crystals with a calcium fluoride feedstock in a low-chlorine graphite optical fluoride crystal crucible having a chlorine content concentration less than 0.3 ppm Cl by weight. The method includes melting calcium fluoride feedstock in the <0.3 ppm Cl graphite crucible to form a low-chlorine calcium fluoride crystal from the melt in the crucible to provide a grown calcium fluoride scatter-free crystal having a chlorine concentration less than 0.25 Cl by weight.

### PRIORITY

This application claim priority of U.S. Provisional Application No. 60/401,822, filed Aug. 7, 2002 and titled “Scatterfree UV Optical Fluoride Crystal Elements for <200 nm Laser Lithography and Method”; which Provisional Application is hereby incorporated by reference in its entirety.

### FIELD OF THE INVENTION

The present invention relates generally to UV transmitting optical fluoride crystals and optical elements therefrom, and particularly to making high quality calcium fluoride optical fluoride crystals and lithography/laser elements with excellent optical qualities for below 200 nm wavelengths utilized in semiconductor circuitry advanced optical microlithography systems.

### BACKGROUND OF THE INVENTION

The burden of the demands for improved performance of computers falls on the lithographic process used to fabricate the integrated circuit chips. Lithography involves irradiating a mask and focusing the pattern of this mask through an optical microlithography system onto a wafer coated with a photoresist. The pattern on the mask is thereby transferred onto the wafer. Decreasing the line-widths of the features on a given wafer brings about advances in performance. The enhanced resolution required to achieve finer line-widths is enabled by decreasing the wavelength of the illumination source. The energies used in lithographic patterning are moving deeper into the UV region. That is, to shorter wavelengths. Optical components capable of reliable performance at these short, deep UV optical microlithography wavelengths are required for the newer lithographic systems. However, there are few materials known to have a high transmittance at 193 nm and 157 nm and to not deteriorate under intense laser exposure. Fluoride crystals, for example, calcium fluoride and barium fluoride crystals, are potential optical materials that have a high transmittance at wavelengths <200 nm. Projection optical photolithography systems that utilize the vacuum ultraviolet wavelengths of light at and below 193 nm provide desirable benefits in terms of achieving smaller feature dimensions. Microlithography systems that utilize vacuum ultraviolet wavelengths in the 157 nm wavelength region have the potential of improving integrated circuits and their manufacture.

The commercial use and adoption of 193 nm and below vacuum ultraviolet (“VUV”) wavelengths, for example, 157 nm, has been hindered by the transmission nature of such deep ultraviolet wavelengths in the 157 nm region through optical materials. The slow progression by the semiconductor industry to the use of VUV light below 175 nm, for example, 157 nm region light, has been also due to the lack of blanks that can be manufactured economically and used to make optically transmissive materials for use in this region. That is, there are difficulties involved in manufacturing blanks which can be identified as high quality and suitable for use in making microlithography optical elements and particularly elements suitable for use in lasers. In order to obtain the benefit of deep ultraviolet photolithography in the VUV 157 nm region in the manufacturing of integrated circuits, for example, by the use of the emission spectrum of a fluorine excimer laser, there is a need for below 200 nm wavelength transmitting optical fluoride crystals that have beneficial optical and highly qualified properties including good transmission below 200 nm and particularly at 193 nm and 157 nm. In addition, the optical fluoride crystals must be able to be manufactured reliably and economically.

The present invention overcomes problems in the prior art and provides a means for economically providing high quality, very low contaminant level, below 200 nm wavelength transmitting optical fluoride crystals that can be used to improve the manufacturing of integrated circuits through the use of vacuum ultraviolet wavelengths. The invention provides for scatter-free, low-chlorine contaminant, high quality metal fluoride crystals, particularly calcium fluoride crystals, that are suitable for use is making optical fluoride crystal lithography elements and particularly excimer laser elements with very low-chlorine contaminant level concentrations.

### BRIEF DESCRIPTION OF THE DRAWINGS

FIG. 1 illustrates a 157 nm laser system using an optical fluoride element made in accordance with the invention.

FIG. 2 illustrates a 193 nm laser system using an optical element made in accordance with the invention.

FIG. 3 illustrates a low-chloride graphite crucible that is used accordance with the invention.

FIG. 4 illustrates a low-chloride crucible according to the invention that is charged with an optical fluoride material suitable for preparing a below 200 nm optical fluoride crystal.

FIG. 5 illustrates an embodiment of the invention having a single low-chloride graphite crucible containing a melt of an optical fluoride material in the melting zone of a furnace.

FIG. 6 illustrates an embodiment of the invention wherein a low-chloride crucible is partially an annealing zone and partially in a melting zone of a furnace, and an optical fluoride crystal is forming in the crucible.

FIG. 7 illustrates an embodiment of the invention wherein a low-chloride crucible containing an optical fluoride crystal in the annealing zone of a furnace. . .

FIG. 8 illustrates an embodiment of the invention wherein optical elements are made from an optical fluoride crystal.

FIG. 9A is a color photograph of a calcium fluoride disk blank under normal lighting.

FIG. 9B is a color photograph showing a red laser beam scatter inspection light detecting scatter in a calcium fluoride crystal disk blank.

FIG. 10 illustrates an embodiment of the invention having a plurality of low-chlorine crucibles in a furnace, the top and bottom crucibles being charges with an optical fluoride powder and the middle crucibles being charged with a pre-melted, densified optical fluoride disk feedstock.

FIG. 11 is a side view illustrating an embodiment of the invention utilizing a plurality of low-chlorine crucibles 62 in a furnace and a lift mechanism for moving the crucibles between the furnace's melting zone and annealing zone.

FIG. 12 is a top view illustrating the use of a plurality of stacks of multiple crucibles in a furnace (see also FIG. 11).

FIG. 13 illustrates an embodiment of the invention using a single low-chlorine crucible containing an optical fluoride feedstock in a furnace having a vacuum port connected to a vacuum pump and a lift mechanism for raising and lowering crucibles.

FIG. 14 is a plot showing contaminant concentration (ppm) in graphite crucibles in accordance with the invention.

FIG. 15 is a plot showing chlorine contamination (ppm) in graphite in accordance with the invention.

FIG. 16 is a plot with an expanded scale showing B, S and Cl contaminant concentration (ppm) in calcium fluoride in accordance with the invention.

### SUMMARY OF THE INVENTION

The invention is directed to a below 200 nm wavelength transmitting optical fluoride lithography crystal, a method of making such crystals, a blank made from the optical crystal and optical elements made from the crystal and/or the blank. The optical fluoride crystal of the invention has a chlorine contamination of less than 0.3 ppm. In preferred embodiments the chlorine contamination is less than 0.25 ppm and most preferably less than 0.2 ppm. The optical fluoride crystals made according the invention, and blanks and elements made therefrom, have a 193 nm transmission >99% and a 157mn transmission >97%.

The method according to the invention includes providing an optical fluoride feedstock having a chlorine content less than 0.5 ppm Cl, providing a crucible for containing the feedstock and preparing the crystal. The crucible is a purified low-chlorine graphite crucible having a chlorine content concentration less than 0.3 ppm Cl. In one embodiment the invention includes melting a <0.5 ppm Cl calcium fluoride feedstock in the <0.3 ppm Cl graphite crucible to form a low-chlorine calcium fluoride crystal from the melt that is then used to provide a grown calcium fluoride crystal having a chlorine contamination level ≦0.25 ppm Cl. Other optical fluoride materials that can be used include the fluorides of magnesium, barium, strontium and lithium.

The method of the invention further includes a method of making a scatter-free optical fluoride crystal suitable for transmitting below 200 nm wavelengths. The method includes providing a optical fluoride feedstock having a chlorine content less than 0.5 ppm Cl and providing a low-chlorine crucible made of a purified graphite having a chlorine content less than 0.3 ppm Cl that can be use to contain an optical fluoride material or to grow an optical fluoride crystal. The method further includes providing a controlled atmosphere furnace suitable for heating an optical fluoride crystal material, loading an optical fluoride feedstock into a low-chlorine crucible, placing the loaded crucible into the furnace, heating the feedstock into a low-chlorine melt and growing an optical fluoride crystal from the melt to provide a grown scatter-free optical fluoride crystal having a chlorine concentration less than 0.25 Cl by weight and a below 200 nm transmission >99%/cm. The method is particularly suitable for providing a scatter-free optical calcium fluoride crystal having a chlorine concentration less than 0.25 ppm Cl, and a below 200 nm transmission >99%/cm.

The invention further directed to a scatter-free optical fluoride lithography crystal element blank for transmitting below 200 nm wavelengths, said blank having a chlorine concentration less than 0.25 ppm Cl and a below 200 nm transmission >99%/cm. The invention particularly directed to a scatter-free calcium fluoride optical lithography element blank for transmitting below 200 nm wavelengths, said blank having a chlorine concentration less than 0.25 ppm Cl, and a below 200 nm transmission >99%/cm.

The invention includes a scatter-free optical fluoride crystal for transmitting below 200 nm wavelengths comprised of a low-chlorine scatter-free fluoride crystal having a chlorine concentration less than 0.2 ppm Cl and a below 200 nm transmission >99%/cm.

### DETAILED DESCRIPTION OF THE INVENTION

As used herein the terms “optical fluoride material”, “optical fluoride crystal”, “optical fluoride element”, “optical fluoride blank” and similar terms means a material or item made of a metal fluoride of general formula MₐF₂ or M_{b}F, where Mₐ is calcium, barium, magnesium or strontium, and M_{b} is lithium. Crystals being mixtures of the foregoing metal fluorides can also be prepared. Calcium fluoride is particularly useful for <200 nm optics and is used herein to exemplify and/or describe the invention and not to limit the invention.

The terms “optical fluoride blank” and “optical fluoride element”, or “blank (or disk blank” and “element”, respectively, refer to blanks and elements made from an optical fluoride crystal.

All “ppm” values given herein are by weight.

In addition, in as far as possible, elements common to the various Figures described herein have been given the same number throughout the Figures.

The invention is directed to an scatter-free optical fluoride crystal having a chlorine contaminant level of less that 0.25 ppm; and to optical blanks and elements, including optical lithography/laser elements made from such crystals that are suitable for the transmission of <200 nm electromagnetic radiation (for example, 157 nm and 193 nm radiation; and to a method of making the crystal. The elements are suitable for use in any <200 nm laser, for example, a F₂ excimer laser. The crystals and elements made therefrom are prepared utilizing an optical fluoride feed stock, preferably one contaminated with less than 0.5 ppm chlorine and low-chlorine graphite crucible having a chlorine contaminant level of less than 0.3 ppm chlorine

The invention is also directed to a method for preparing optical fluoride crystals, including blanks and the elements made therefrom, that contain <0.25 ppm Cl and have a <200 nm transmission of >99%. Generally exemplifying the method of the invention, the method uses an optical fluoride feedstock 52 having a chlorine content less than 0.5 ppm Cl, a chlorine content ≦0.4 ppm Cl, preferably ≦0.25 ppm Cl, and preferably ≦0.2 ppm Cl. The feedstock is placed in a crucible 62 suitable for growing <25 ppm Cl crystals. The crucible 62 is made of a purified low-chlorine graphite G having a chlorine content less than 0.3 ppm Cl. Preferably, the low-chlorine graphite G has a chlorine content≦0.25 ppm Cl, more preferably ≦0.2 ppm Cl. Further details of the invention are given with reference to the accompany figures and examples given below.

The invention, with regard to both the crystal(s) and the method(s), further includes annealing the optical fluoride crystal in to a low birefringence crystal suitable for <200 nm lasers. The annealed crystal can be used to prepare low birefringence optical blanks and elements.

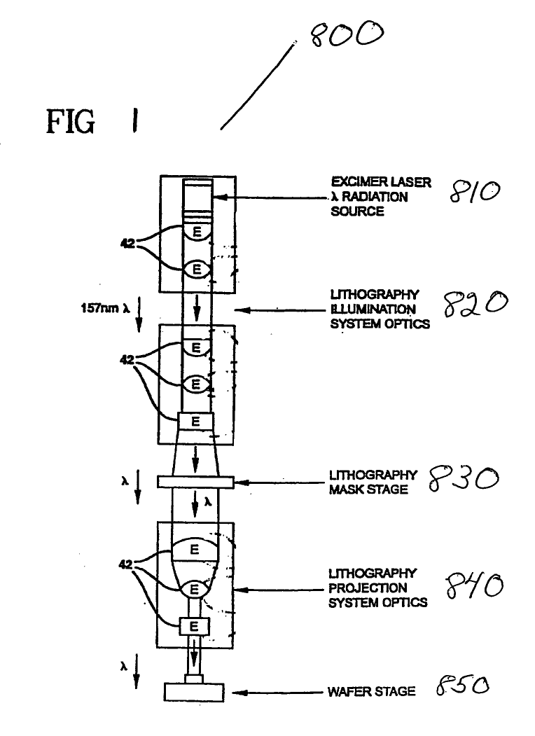

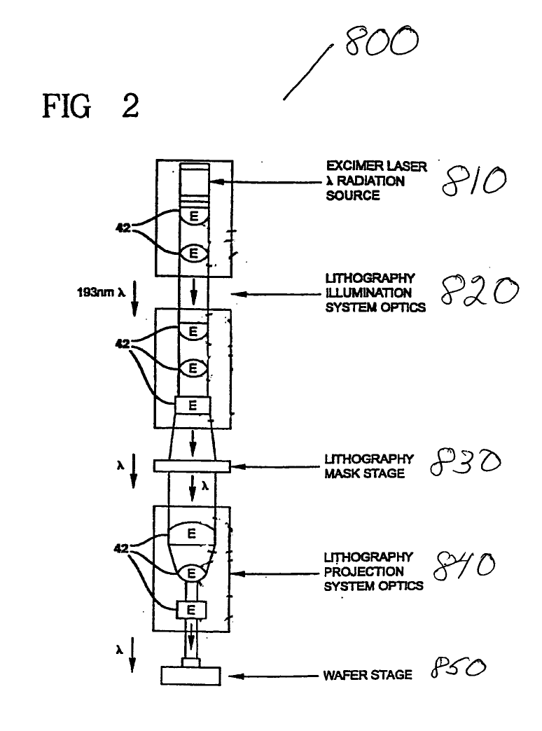

In accordance with the invention, FIGS. 1-2 illustrate laser systems containing below 200 nm wavelength optical elements (E) 42. These elements are formed from below 200 nm wavelength transmitting optical fluoride crystals or blanks made in accordance with the invention. The elements 42 are preferably formed from low-chlorine, scatter-free optical fluoride crystals, and more preferably from low-chlorine, scatter-free optical calcium fluoride crystal blanks.

FIG. 1 illustrates an optical lithography system/method 800, which includes an F₂ excimer laser with low-chlorine scatter-free optical fluoride crystal optical elements that utilized below 200 nm wavelengths centered about 157 nm. In particular, FIG. 1 illustrates in a general way the excimer laser radiation source 810, the lithography illumination system optics 820, the lithography mask stage 830, the lithography projection system optics 840 and the wafer stage 850 of an optical lithography system. The 157 nm radiation, represented by δ, is shown to the left of FIG. 1 as it progresses from the source 810 to the wafer stage 850.

FIG. 2 shows an optical lithography system/method 800 which includes an ArF excimer laser with low-chlorine scatter-free optical fluoride crystal optical elements. The lithography/laser system of FIG. 2 utilizes below 200 nm wavelengths centered about 193 nm and includes below 200 nm optical element 42 (E) as are also shown in FIG. 1. The elements represented by numerals 810-850 are the same as for FIG. 1. The 193 nm radiation is represented by δ.

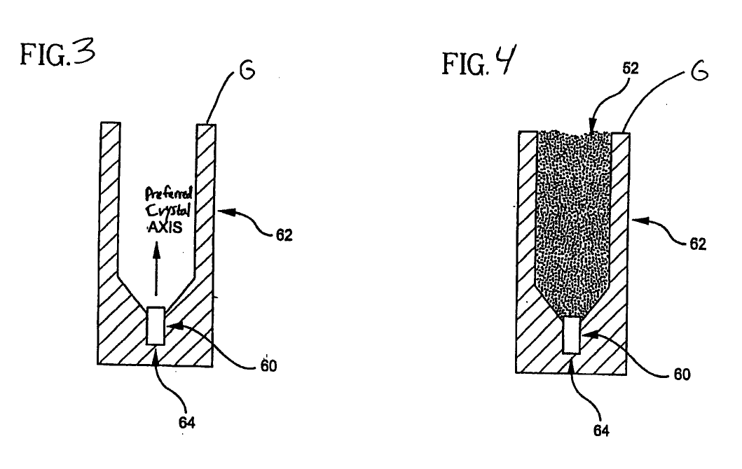

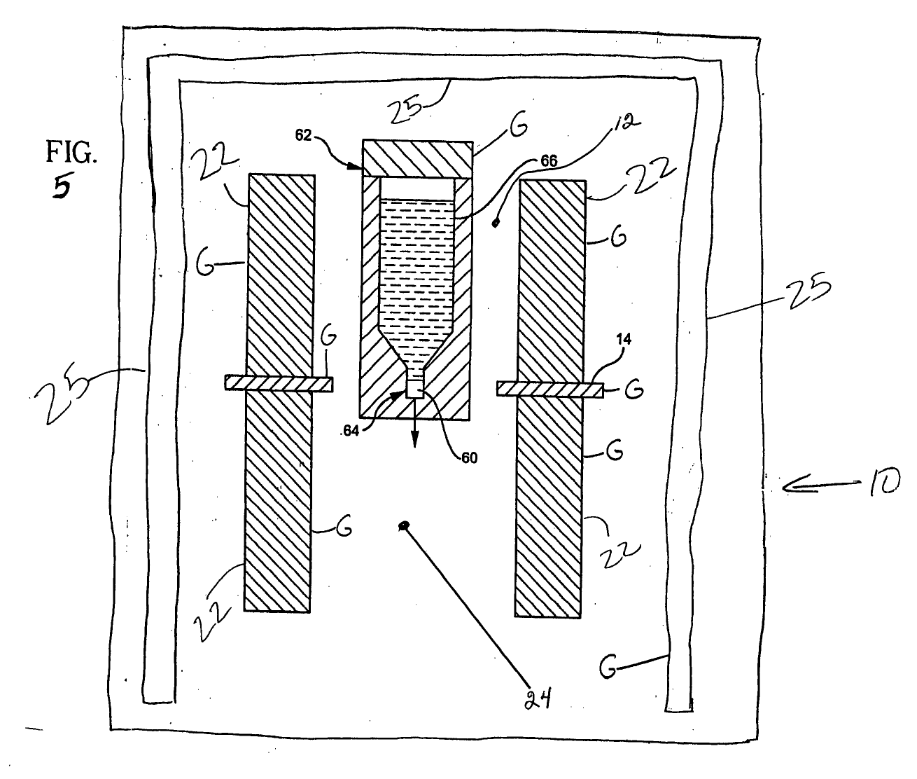

FIG. 3 illustrates a crucible used in practicing the invention and in making optical fluoride crystals used to form the elements 42 used in the lasers of FIGS. 1 and 2. Crucible 62 is made of low-chlorine (<0.3 ppm Cl) graphite G and has a receiving reservoir 64 for placement of a seed crystal 60 in which the preferred axis of the seed crystal for crystal growth is oriented as indicated by the arrow. The seed crystal is preferably an optical fluoride crystal having <0.3ppm Cl. FIG. 4 is similar to FIG. 3, and further illustrates the loading of an optical fluoride material 52 into the crucible 62. The optical fluoride material 52 preferably has a chlorine content of less than 0.5 ppm. The optical fluoride material 52 can be any of those described herein, including mixtures thereof.

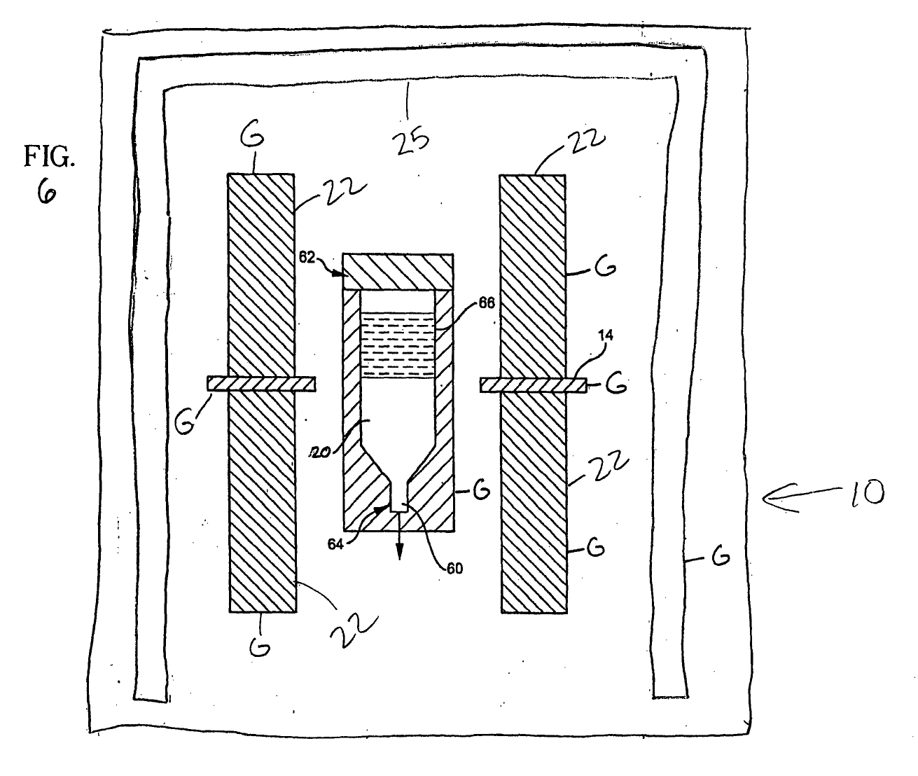

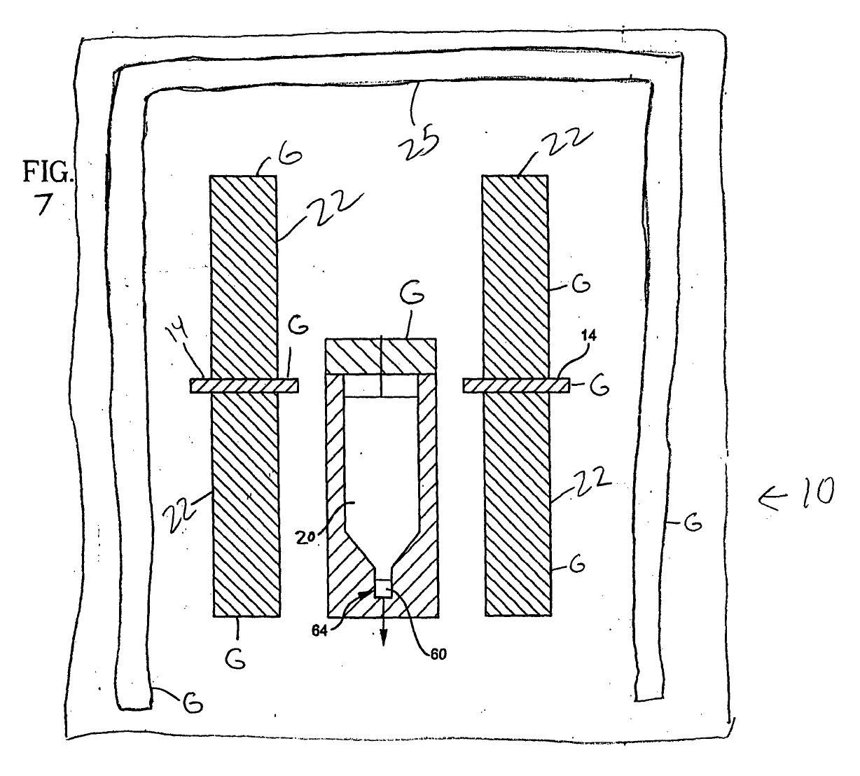

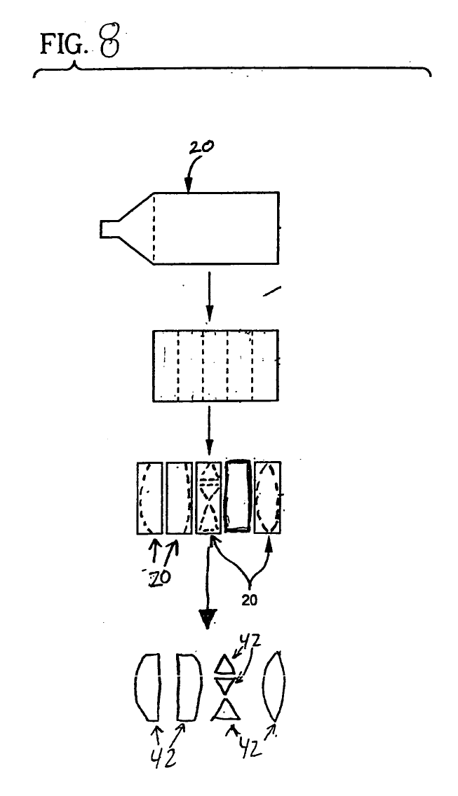

FIG. 5 illustrates a single crucible 62 (shown as lidded) as described in FIGS. 3 and 4 that has been placed in a furnace 10. Furnace 10 has an upper melting chamber (zone) 12 and a lower annealing chamber (zone) 24 that are separated by a diaphragm (baffle) 14, heating elements 22 that are preferably made of a low-chlorine (<0.3 ppm Cl) graphite material G, and an insulation material 25 preferably made of a low-chlorine (<0.3 ppm Cl) graphite material G. Diaphragm 14 is made of a low-chlorine (<0.3ppm Cl) graphite material. Furnace 10 also has elements (not illustrated) for controlling the atmosphere within; for example, ports for the application of vacuum and the admission or exit of gaseous substances. The reservoir 60 containing seed crystal 64 is located at the baffle. As illustrated in FIG. 5, crucible 62 has been placed into the upper melting zone 24 and the optical fluoride charge 52 (see FIG. 4) has been melted to form a melt 66. After the optical fluoride charge 52 has melted to form melt 66, the crucible 62 is lowered from the melting zone 12 into the annealing zone 14 as is illustrated in FIG. 6 (showing part of the crucible in the melting zone and part in the annealing zone). As the crucible is lowered and melt 66 cools, seed crystal 64 initiates the growth of optical fluoride crystal 20 from melt 66. FIG. 6 also illustrates a portion of melt 66 remaining atop crystal 20, Further crystal growth from melt 66 will occur as crucible 62 is further lowered from the melting zone 12 into the annealing zone 24. FIG. 7 depicts crucible 6 fully lowered into the annealing 24 and the melt 66 fully converted into optical fluoride crystal 20. In accordance with the invention, the optical fluoride crystal 20 made in as described above has a chlorine content of less than 0.25 ppm and is a scatter-free optical fluoride crystal.

As shown in FIG. 8 a grown fluoride crystal, for example, a calcium fluoride crystal, is formed into optical fluoride crystal blanks which are then shaped into optical elements 42 that can be utilized as illustrated in FIGS. 1 and 2. To ensure a scatter-free optical fluoride crystal blank and element made therefrom, the method preferably includes transmitting a scatter inspection light into the grown calcium fluoride crystal and inspecting the crystal for an observable level of scatter to provide a scatter-free calcium fluoride lens blank.

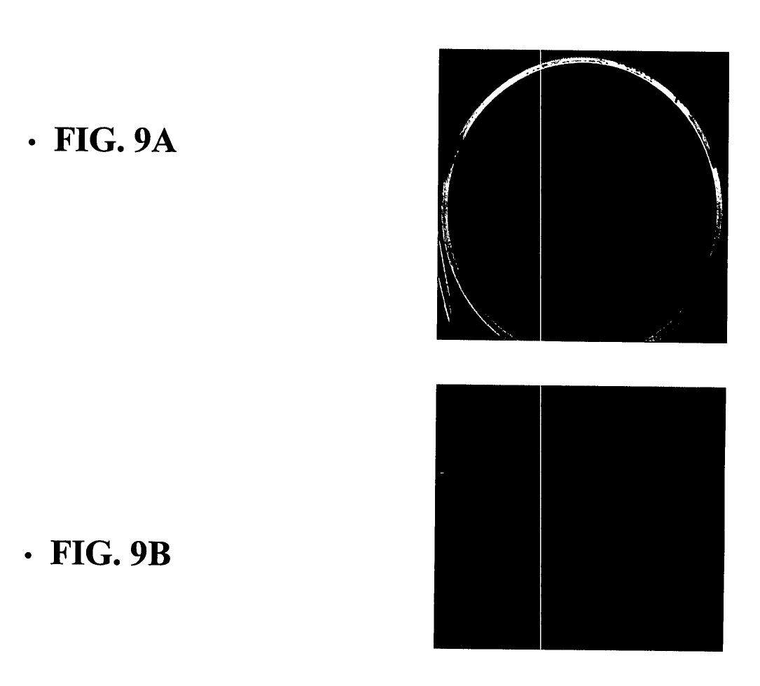

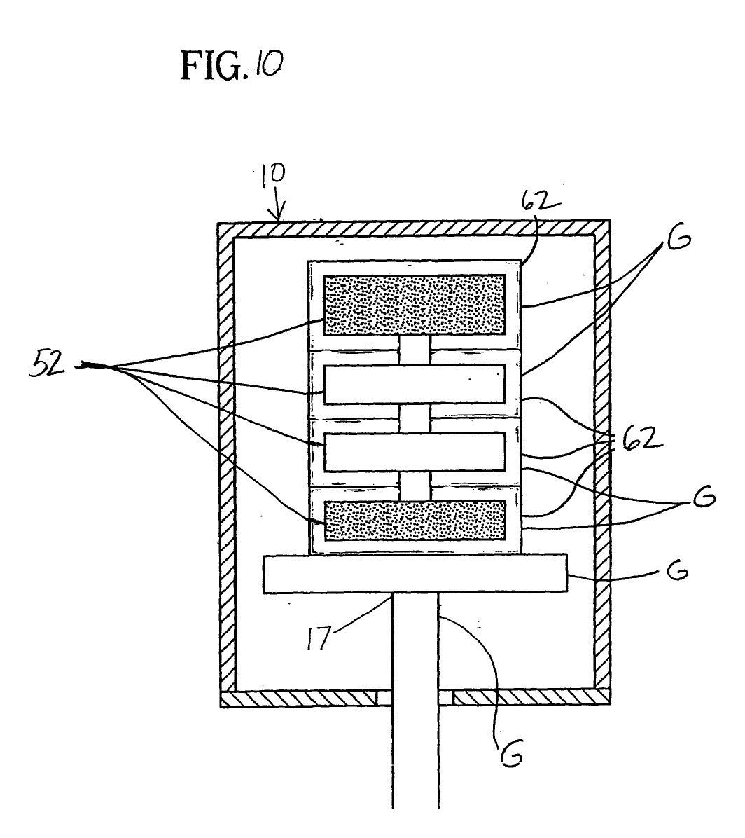

FIG. 9A illustrates a scatter-free optical fluoride crystal 20 where a scatter inspection light 44 is able to transmit through the crystal as an uninhibited light beam.

FIG. 9B shows an optical fluoride crystal with scatter where a scatter inspection light 44 is scattered and progressively dispersed along the length of the beam path. Preferably the scatter inspection light is a collimated laser beam.

FIG. 9C is a color photograph under normal lighting of a calcium fluoride disk blank.

FIG. 9D is a color photograph showing a red laser beam scatter inspection light detecting scatter in a calcium fluoride disk blank. In FIG. 9D the normal lighting of the calcium fluoride blank of FIG. 9C has been turned off. In a scatter-free calcium fluoride crystal disk blank one would not see any red streak in the crystal since there would be nothing to reflect or scatter the light in the middle of the crystal. In a preferred embodiment the method includes transmitting a collimated laser light beam scatter inspection light into a grown calcium fluoride crystal 20 and inspecting the crystal for an observable level of scatter to provide a scatter-free calcium fluoride lens blank with a chlorine concentration less than 0.2 ppm Cl by weight. Preferably scatter-free calcium fluoride crystal 20 has a chlorine concentration≦0.2 ppm and a 193 nm transmission >99%/cm. Preferably scatter-free calcium fluoride crystal 20 has a chlorine content≦0.2 ppm and a 157 nm transmission >97%/cm., preferably >98%/cm transmission, and preferably >99%/cm transmission.

In practicing the invention, providing an optical fluoride crystal crucible of purified low-chlorine graphite includes inhibiting chlorine contact and contamination of the graphite. Preferably a starting graphite billet is machined to the crucible shape, then purified with a purifying gas and purged of gas to remove contaminating gases and chlorine. During crucible purification with purifying gases it is preferred that graphite test coupons be treated along with the crucible. The test coupons are monitored for chlorine contamination. Vacuum may also be used to eliminate chlorine contaminant during the purification process. In a preferred embodiment of the crucible purification process, chlorine contaminants are removed from the graphite material by repeated heating and exposure to a vacuum within a heated evacuated chamber to effect the thermal, gaseous removal of chlorine contaminants. The chlorine content of the graphite G is checked with a glow discharge mass spectroscopy, for example, by analysis of the coupons. The crucible graphite G has a chlorine content <0.3 ppm, preferably no greater than 0.25 ppm Cl, and more preferably no greater than 0.2 ppm Cl. and is referred to herein as a low-chlorine graphite crucible.

The invention includes a method of making a scatter-free optical fluoride crystal for transmitting below 200 nm wavelengths. The method includes providing a low-chlorine content optical fluoride feedstock 52 having a chlorine content less than 0.5 ppm Cl and providing a crucible 62 of purified graphite G having a chlorine content less than 0.3 ppm Cl for containing the feedstock and resulting crystal. The feedstock is heated in a suitable controlled atmosphere crystal furnace 10. In accordance with the method of the invention, a feedstock 52 is loaded into a crucible 62 and the loaded crucible is placed into furnace 10 and heated to form a low-chlorine melt. The melt is used to grow a scatter-free optical fluoride crystal 20 having a chlorine concentration less than 0.25 ppm Cl by weight and a below 200 nm transmission>98/cm, and preferably greater than 99%. In a preferred embodiment the method provides for the use low-chlorine feedstock 52 having a chlorine content≦0.4 ppm Cl, more preferably ≦0.25 ppm Cl, and still more preferably ≦0.2 ppm Cl.

The scatter-free optical fluoride crystal grown in accordance with the invention has a chlorine content less than 0.2 ppm, preferably with a 193 nm transmission >99%/cm and preferably with a 157 nm transmission >98%/cm. The optical fluoride material used in accordance with the invention can be calcium fluoride (CaF₂), barium fluoride (BaF₂), strontium fluoride (SrF₂), magnesium fluoride (MgF₂), lithium fluoride (LiF) and mixture of any of the foregoing. In one form the low-chlorine content optical fluoride feedstock is a synthetic powder. In another form the feedstock is a pre-melted, low-chlorine optical fluoride material made from melting and solidifying a synthetic powder.

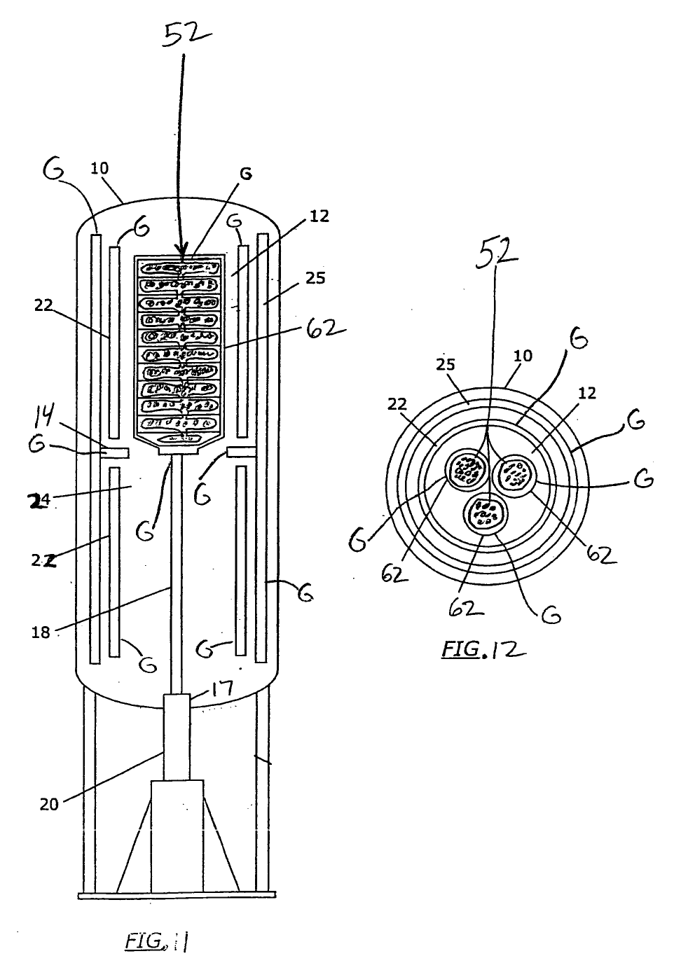

FIG. 10 shows an embodiment of the invention where low-chlorine synthetic powder optical fluoride feedstock 52 is loaded into the top and bottom crucibles 62 of a stack of four low-chlorine crucibles 62 and the middle two crucibles 62 are loaded with a pre-melted densified solid optical fluoride disk feedstock 52 made from a low-chlorine powder. The crucibles 62 containing the feedstocks are placed in a controlled atmosphere furnace 10. The furnace 10 of FIG. 10 includes a lift mechanism 17 for supporting the stack of interconnected crucibles and for lowering and raising the stack of crucibles. As used in accordance with the invention, when the optical fluoride material has melted, the stack is progressively lowered through a crystal growth thermal gradient formed in the furnace by heating elements and insulation (not shown in FIG. 10, see FIG. 11). Preferably the crucible support lift 17 is formed from low-chlorine (<0.3 ppm Cl) graphite G.

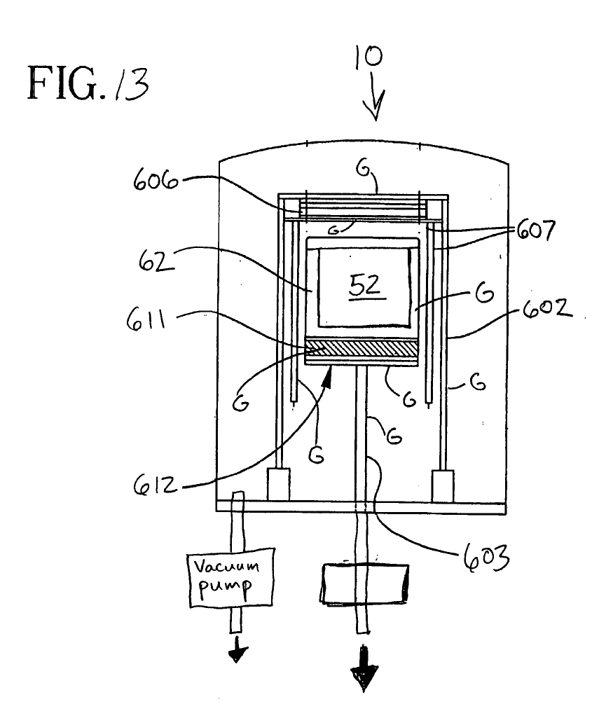

FIGS. 11 and 12 show embodiments of the invention where the optical fluoride feedstock 52 is loaded into low-chlorine graphite crucibles 62 and placed in a controlled atmosphere vacuum furnace 10 that in which elements thereof are made of a low-chlorine graphite G that has a chlorine content less than 0.3 ppm Cl in order to facilitate production of a scatter-free crystal with less than 0.25 ppm chlorine. The controlled atmosphere furnace 10 of FIGS. 11 and 12 has a melting chamber 12 and an annealing chamber 24. Lift mechanism 17 is coupled to the stack of crucibles 62 to lower the stack from the melting chamber into the annealing chamber, preferably with support rod 18 comprised of low-chlorine (<0.3 ppm Cl) graphite G which can be raised and lowered by a lift actuator 20 outside the controlled atmosphere containment body of furnace 10.

The melting chamber and the annealing chamber have heating elements 22 for maintaining an appropriate optical fluoride crystal treatment temperature inside them, with heating elements 22 preferably comprised of low-chlorine (<0.3 ppm Cl) graphite G. The heating elements can be continuous through both chambers or can be separate for the heating and annealing zones. The elements can also be separately controlled to provide maximum flexibility regarding temperature control. Heat shielding insulation 25 is provided around heating elements 22 to contain heat in the chambers. The insulation 25 is preferably made of a low chlorine (<0.3 ppm Cl) graphite G. A diaphragm (baffle) 14 separates the upper melting chamber zone from the lower annealing chamber zone formed by lower heating elements 22. The diaphragm is preferably made from a low chlorine (<0.3 ppm Cl) graphite G. The diaphragm 14 forms an optical fluoride crystal growing thermal gradient between the two zones.

FIG. 13 shows an embodiment of the invention with a low-chlorine feedstock 52 is contained in a low-chlorine graphite G crucible 62 in a controlled atmosphere crystal furnace 10. The furnace 10 has low-chlorine (<0.3 ppm Cl) graphite furnace components G such as support structure 602, crucible support lift column 603, primary insulating heat shields 606, primary heater elements 607, secondary heater element 611, and secondary insulating heat shields 612. The graphite crucible 62 can be, for example, of a size of about 8 inches in diameter, with furnace 10 having a diameter in the range of 20 to 40 inches and a height of approximately 40 inches with insulating heat shields 606 and 612 being ¼ to ½ inch thick pieces of insulating graphite G having a low-chlorine content (<0.3 ppm Cl).

The invention includes a method of making a scatter-free optical fluoride crystal 20 for transmitting below 200 nm wavelengths. The method includes providing a controlled atmosphere furnace 10 having elements comprised of a low-chlorine graphite material G, loading an optical fluoride material (20, 52, 66) having <0.5ppm Cl into purified graphite crucible 62 (<0.3 ppm Cl) having a reservoir in which a seed crystal of an optical fluoride material has been placed, placing the loaded crucible 62 in the furnace 10, heating the optical fluoride material in the furnace to obtain a melt of the optical fluoride material, lowering the temperature of the melt in a selected manner to thereby affect crystallization of the melt induced by the seed crystal, cooling the resoling crystal to ambient temperature, and removing the crystal from the crucible to obtain a scatter-free optical fluoride crystal having a chlorine concentration less than 0.25 ppm C and a below 200 nm transmission >99%/cm. Preferably the scatter-free optical fluoride crystal has a transmission >98%/cm in the range of 157 to 199 nm. Preferably the made scatter-free optical fluoride crystal has a chlorine concentration ≦0.2 ppm. Preferably the low-chlorine graphite has a chlorine content ≦0.25 more preferably ≦0.2 ppm. In further embodiments and aspects, the method includes annealing the fluoride crystal into a low birefringence crystal at temperatures below the melting point of the crystal and forming a crystal growth thermal gradient for growing an optical fluoride crystal.

The invention includes a scatter-free calcium fluoride crystals and blanks and lithography elements made therefrom. The calcium fluoride crystals, blanks and elements made in accordance with the invention contain 0.25 ppm Cl and have a below 200 nm transmission >99%/cm. In addition, the calcium fluoride crystal preferably has a sulfur content less than 0.2 ppm, more preferably less than 0.1 ppm. Preferably the calcium fluoride crystal has a combined chlorine and sulfur concentration less than 0.3 ppm Cl+S, more preferably <0.25 ppm, and more preferably <0.2 ppm. Preferably the calcium fluoride crystal blank has a transmission >98%/o/cm in the range of 157 to 199 um. Preferably the scatter-free optical fluoride crystal blank calcium fluoride crystal chlorine concentration is less than 0.2 ppm Cl, has a 193 nm transmission >99%/cm and has a 157 nm transmission >99%/cm.

We have found that chlorine contamination is detrimental to calcium fluoride below 200 nm wavelength transmitting optical fluoride crystals and optical lithography laser elements made therefrom, and that it is a source of scatter in <200 nm transmitting crystals. The scatter defect observed in CaF₂ optical fluoride crystals (such as detected in FIG. 9) is due to chlorine from purified graphite crucibles dissolving into the molten calcium fluoride, as well as chlorine present in the feedstock. The result can be chlorine concentrations in the CaF₂ greater than about 0.2 to 0.25 ppm, and the presence of chlorine can result in the formation of scatter. We have found that if a graphite crucible's chlorine content is >0.3 ppm, enough chlorine can dissolve into the molten CaF₂ to cause scatter in the crystal grown from the calcium fluoride molten melt. The level of residual chlorine in the graphite can not only cause scatter but it can also adversely affect wavelength transmissions below 170 nm. We have found that chlorine concentrations in the range of about 0.2 to 0.25 ppm in CaF₂ can cause poor transmission below 170 nm. Glow Discharge Mass Spectroscopy (GDMS) is the preferred technique for chemical analysis of both graphite and optical fluoride crystal material for measuring and monitoring low-chlorine levels. In accordance with the invention, graphite coupons are processed along with the graphite components being machined and purified. These coupons are witness samples to the graphite to allow for tracking and monitoring of chlorine levels in the graphite furnace components such as crucibles purified. The graphite coupons are analyzed by Glow Discharge Mass Spectroscopy to confirm that the crucibles have acceptable purity prior to use in the optical fluoride crystal furnace. We have identified chlorine as the source of scatter and that graphite containing chlorine can be the source of chlorine contamination forming the scatter in crystals treated in the presence of the graphite inside the optical fluoride crystal controlled atmosphere vacuum furnace.

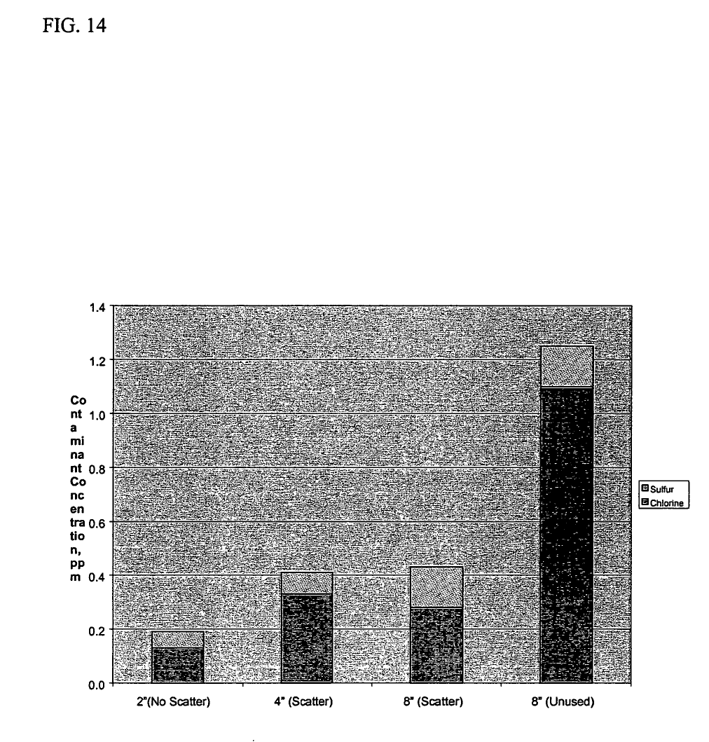

FIG. 14 illustrates how scatter can be derived from contaminants in the graphite crucibles. The crucibles, left to right in the Figure, were (1) a 1.9 inch diameter graphite crucible, (2) a 4.1 inch diameter graphite crucible, (3) a first 7.5 inch crucible and (4) a second 7.5 inch diameter crucible. All crucibles were purified. Crucible 1 was used more than twice to prepare crystals. Crucibles 2 and 3 were used once or twice to prepare crystals. Crucible 4 was unused. The last crystal prepared in crucible 1 produced a crystal that showed no scatter. The crystals produced by crystals 2 and 3 showed scatter. These results indicate that the production of scatter in a crystal correlates with a crucible having a chlorine content greater than 0.3 ppm, and/or higher levels of chlorine and sulfur. These analytical results indicate:

(a) the importance of purifying the crucible so that the chlorine content is less than 0.3 ppm;

(b) that repeated use of a crucible for growing crystals lower the chlorine content of the crucible; and

(c) that chlorine migration from the crucible to the feedstock is a factor in producing scatter in crystals.

The results also seem to indicate that scatter is independent of sulfur at current concentrations in the crucible, and also the current concentrations of other contaminants including boron.

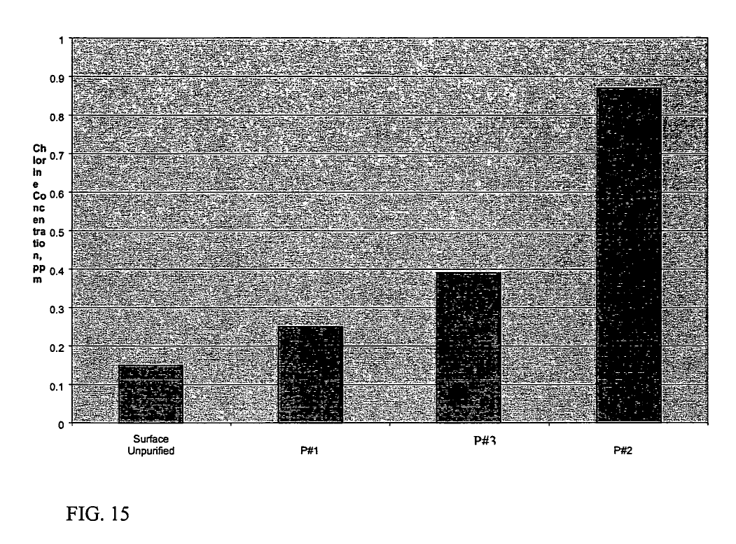

To further understand the source of the scatter contamination and baseline contamination levels in the graphite suppliers' processes we designed the following experiment. A single billet of high quality, commercially available graphite was acquired and cut two large sections. The two sections of the billet to two different graphite machinists (M#1, M#2) and each was made into a number of 4-inch graphite crucibles and into graphite coupons Crucibles from each machinist were then sent to three different purifiers (P#1, P#2, P#3) for purification as taught herein. The results of this designed experiment are summarized in Table 1 and FIG. 15.

Table 1 indicates that only the crucibles did not exhibit any scatter were those purified by purifier P#1. FIG. 15 is a GDMS analysis showing the average contaminant level of two coupons from the 4-inch crucible purification performed at each of the three purifiers. As in the initial analysis (FIG. 14), the results indicate that a chlorine content >0.3 ppm in graphite correlates with the occurrence of scatter. The analyses show that the scatter maybe independent of the sulfur at the current concentration levels; that the scatter maybe independent of all other analyzed graphite contaminants, including boron, and that purification by most graphite purifiers may increase the chlorine content in graphite when the initial concentration of Cl in the graphite is low.

TABLE 1
Summary of 4-inch Crucible Scatter

| Crucible | Furnace | Machined | Purified | Scatter |
|---|---|---|---|---|
| 6A | A | M# 1 | P# 1 | No |
| 8A | | M# 1 | P# 2 | Yes |
| 5A | | M# 1 | P# 3 | Yes |
| 9A | | M# 1 | P# 3 | Yes |
| 8B | | M# 1 | P# 1 | No |
| 3B | | M# 2 | P# 1 | No |
| 1B | | M# 2 | P# 2 | Yes |
| 6B | | M# 2 | P# 3 | Yes |
| 7B | | M# 2 | P# 3 | Yes |
| 3 | | | | No |
| Control crucible | | | | |
| 1A | B | M# 1 | P# 1 | No |
| 4A | | M# 1 | P# 3 | Yes |
| 3A | | M# 1 | P# 2 | Yes |
| 4B | | M# 2 | P# 1 | No |
| 2B | | M# 2 | P# 3 | Yes |
| 10B | | M# 2 | P# 2 | Yes |
| 7A | | M# 1 | P# 2 | Yes |
| 5B | | M# 2 | P# 2 | Yes |
| 10A | | M# 1 | P# 1 | No |
| L | | | | No |
| Control Crucible | | | | |

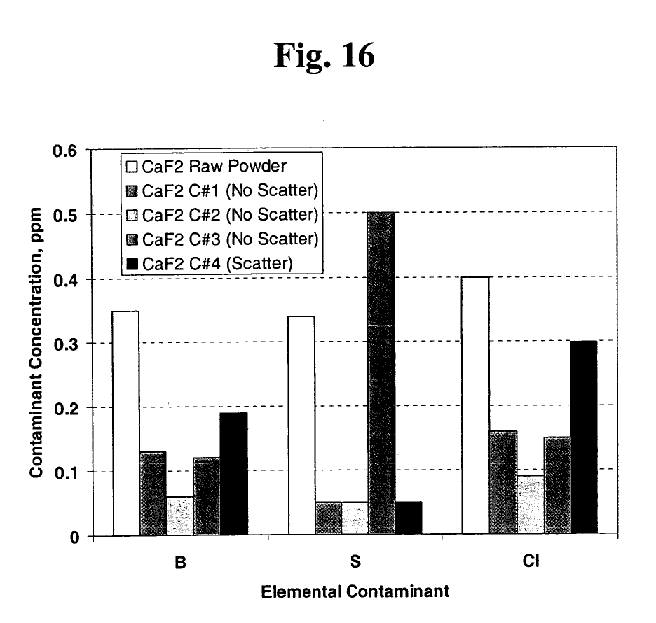

FIG. 16 shows the GDMS analysis for B, S and Cl in the raw synthetic powder used to prepare crystals and four different CaF₂ crystal material samples. These samples are:

untreated raw synthetic material powder,

CaF₂ crystal C#1 with No Scatter,

CaF₂ crystal C#2 from the 4-inch P#1-purified crucible with No Scatter,

CaF₂ crystal C#3 from the 4-inch P#3-purified crucible with No Scatter, and

CaF₂ crystal C#4 from the 4-inch P#2-purified crucible with Scatter.

These results show that the occurrence of scatter varies consistently only with the content of chlorine and boron. However, since the boron concentration in graphite does not vary consistently with the occurrence of scatter, and it is believed that boron does not influence the development of scatter. The results also indicate that the maximum allowable amount of chlorine in a scatter-free CaF₂ crystal is in the range approximately 0.20 to 0.25 ppm and that chlorine can be present in relatively high levels in the untreated feedstock material. The chlorine can be removed from the graphite crucibles by an evaporative heat treatment method such as described herein. In addition, chlorine can be removed from the crucibles and the feedstock by, for example, a pre-melting method, and more preferably by pre-melting in the presence of a fluorinating agent ( for example, PbF₂ SnF2 and other fluorinating agents known in the art ) to provide a low-chlorine feedstock by dechlorination with the fluorinating agents.

It will be apparent to those skilled in the art that various modifications and variations can be made to the present invention without departing from the spirit and scope of the invention. Thus it is intended that the present invention cover the modifications and variations of this invention provided they come within the scope of the appended claims and their equivalents.

We claim:

1. A scatter-free optical fluoride crystal for transmitting below 200 nm wavelengths comprising an optical fluoride crystal having a chlorine concentration of less 0.25 ppm Cl

2. A scatter-free according to claim 1, wherein said optical fluoride crystal is selected from the group consisting of calcium fluoride, barium fluoride, magnesium fluoride, strontium fluoride and lithium fluoride, and mixtures thereof.

3. The scatter-free crystal according to claim 1, wherein said optical fluoride crystal is a calcium fluoride crystal having a below 200 nm transmission >99%.

4. The scatter-free crystal according to claim 1, wherein said optical fluoride crystal is a calcium fluoride crystal having a chlorine concentration of less than 0.2 ppm Cl and a 193 nm transmission >99%.

5. The scatter-free crystal according to claim 1, wherein said optical fluoride crystal is a calcium fluoride crystal having a chlorine concentration of less than 0.2 ppm Cl and a 157 nm transmission >99%.

6. The scatter-free crystal according to claim 1, wherein said optical fluoride crystal is a calcium fluoride crystal having a chlorine concentration of less than 0.2 ppm Cl and a 157 nm transmission >99%.

7. The scatter-free crystal according to claim 1, wherein said optical fluoride crystal is a calcium fluoride crystal having a combined chlorine and sulfur concentration Cl+S of less than 0.3 ppm Cl and a transmission >98% in the 157-199 nm range.

8. The scatter-free crystal according to claim 7, wherein Cl+S is less than 0.2 ppm and a 157 nm transmission >99%.

9 A method of making a scatter-free below 200 nm wavelength transmitting optical fluoride crystal, said method comprising:
providing a optical fluoride feedstock having a chlorine content less than 0.5 ppm Cl by weight,
providing crucible comprised of a low-chlorine graphite having a chlorine content less than 0.3 ppm Cl and placing said feedstock into said crucible,
melting said feedstock in said crucible to form a low-chlorine optical fluoride melt, and
growing an optical fluoride crystal from said melt,
wherein said grown optical fluoride crystal having a chlorine concentration less than 0.25 ppm Cl.

10. The method according to claim 9, wherein the feedstock is selected from the group consisting of calcium fluoride, barium fluoride, magnesium fluoride, strontium fluoride and lithium fluoride, and mixtures of any of the foregoing.

11. A method as claimed in 9 wherein the optical fluoride crystal is a calcium fluoride crystal, and said method includes transmitting a scatter inspection light into said grown optical fluoride crystal and inspecting the crystal for an observable level of scatter to provide a scatter-free optical fluoride lens blank with a chlorine concentration less than 0.2 ppm Cl by weight.

11. A method as claimed in 9 wherein said feedstock chlorine content is ≦0.4 ppm.

12. A method as claimed in 9 wherein said feedstock is calcium fluoride having a chlorine content is ≦0.25 ppm, said crucible graphite chlorine content is ≦0.25 ppm, and said grown calcium fluoride crystal has a chlorine concentration ≦0.2 ppm.

13. A method as claimed in 12 wherein said grown calcium fluoride crystal has a 193 nm transmission >99%/cm.

14. A method as claimed in 12 wherein said grown calcium fluoride crystal has a 157 nm transmission >97 %/o/cm.

15. A method of making a scatter-free optical fluoride crystal for transmitting below 200 nm wavelengths, said method including:
providing a low-chlorine content optical fluoride feedstock having a chlorine content less than 0.5 ppm Cl,
providing an optical fluoride crystal crucible for containing an optical fluoride crystal, said crucible comprised of a purified graphite having a chlorine content less than 0.3 ppm Cl,
providing a controlled atmosphere optical fluoride crystal furnace for heating an optical fluoride crystal material,
loading said optical fluoride feedstock and said optical fluoride crystal crucible into said optical fluoride crystal furnace,
heating said feedstock into a low-chlorine melt and
growing an optical fluoride crystal from said melt to provide a grown scatter-free optical fluoride crystal having a chlorine concentration less than 0.25 ppm Cl and a below 200 nm transmission >99%/cm .

16. A method as claimed in claim 15, wherein said optical fluoride feedstock is selected from the group consisting of calcium fluoride, barium fluoride, magnesium fluoride, strontium fluoride and lithium fluoride.

17. A method as claimed in claim 15 wherein said low-chlorine content optical fluoride feedstock is selected from the group consisting of a synthetic powder and a pre-melted fluoride crystal material.

18. A method of making an optical calcium fluoride crystal, including blanks and elements made therefrom, for transmitting below 200 nm wavelengths, said method including:
providing a controlled atmosphere optical fluoride crystal furnace for heating an optical fluoride crystal material, said furnace containing a calcium fluoride crystal material and a purified graphite having a chlorine content less than 0.3 ppm Cl by weight,
heating said calcium fluoride crystal material in said furnace containing said graphite having a chlorine content less than 0.3 ppm Cl to provide a scatter-free optical calcium fluoride crystal having a chlorine concentration less than 0.25 ppm Cl by weight and a below 200 nm transmission >99%/cm.
